(19) United States
(12) Patent Application Publication
(10) Pub. No.: US 2009/0047777 A1
(43) Pub. Date: Feb. 19, 2009

(54) SEMICONDUCTOR DEVICE AND METHOD OF MANUFACTURING THE SAME

(75) Inventor: Hajime NAGANO, Yokkaichi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 12/117,231

(22) Filed: May 8, 2008

(30) Foreign Application Priority Data
May 11, 2007 (JP) 2007-126851

(51) Int. Cl. H01L 21/3205

(52) U.S. Cl. 438/593; 257/E21.294

(57) ABSTRACT

A method of manufacturing a semiconductor device includes forming a gate electrode film on a semiconductor substrate via a gate insulating film; forming a mask film on the gate electrode film; separating the gate electrode film by using the mask film to form a plurality of gate electrodes; forming a first insulating film between the plurality of gate electrodes so that an upper portion of the first insulating film is lower than an upper surface of the gate electrode; forming a second insulating film on the upper portion of the first insulating film, removing the mask film so as to expose the gate electrode, and cleaning an exposed surface of the gate electrode by wet etching process with selectivity to the second insulating film so as to remove a native oxide film.

### CROSS-REFERENCE TO RELATED APPLICATIONS

This application is based upon and claims the benefit of priority from the prior Japanese Patent Application No. 2007-126851, filed on, May 11, 2007 the entire contents of which are incorporated herein by reference.

### FIELD

The present disclosure is directed to a semiconductor device provided with a gate electrode and a method of manufacturing the same.

### BACKGROUND

A NAND flash memory typically employed as memory elements for multimedia cards is disclosed, for example, in JP 2006-60138 A. The disclosed flash memory achieves integration by configuring multiple memory cells having matrix-aligned gate electrodes composed of laminated layers formed over a semiconductor substrate via a gate insulating film. Further integration of memory cells are required to increase the storage capacity of flash memories. Integration of memory cells requires narrower spacing between the memory cells which consequently reduces the spacing between the laminated gate electrodes. Narrower spacing between the neighboring laminated gate electrodes results in increase in the aspect ratio which impairs gap fill capabilities in filling the gate electrode gaps with an insulating film serving as an inter-electrode insulating film. Such conditions provide grounds for increased instances of seam formation in the insulating films. Etch process such as wet etch performed after filling the gate electrode gaps with the insulating film increases the size of the seams in case the insulating film is composed of a film having weak etch tolerance. The increase in the size of seams may allow unwanted films to be formed in the void developed from the seams when forming conductive or insulating films in the subsequent steps and may lead to device errors. Such problems are observed in a single layer gate electrode as well as in a laminated gate electrode.

### SUMMARY

According to an aspect of the invention, there is provided a semiconductor device a method of manufacturing method comprising forming a gate insulating film on a semiconductor substrate; forming a gate electrode film on the gate insulating film; forming a mask film on the gate electrode film; separating the gate electrode film by using the mask film as a mask pattern to form a plurality of gate electrodes; forming a first insulating film between the plurality of gate electrodes so that an upper portion of the first insulating film is lower than an upper surface of the gate electrode; forming a second insulating film on the upper portion of the first insulating film so as to cover the first insulating film removing the mask film leaving the second insulating on the first insulating film so as to expose the gate electrode; and cleaning an exposed surface of the gate electrode by wet etching process with selectivity to the second insulating film so as to remove a native oxide film.

According to an aspect of the invention, there is provided a semiconductor device comprising a semiconductor substrate including an upper surface; a gate insulating film formed on the upper surface of the semiconductor substrate; a plurality of gate electrodes formed on the gate insulating film; an inter-electrode insulating film formed on the gate insulating film between the plurality of gate electrodes, the inter-electrode insulating film including a seam and including a silicon oxide film; a cap insulating film formed so as to cover the inter-electrode insulating film, the cap insulating film including a silicon nitride film containing a boron (B); and an inter layer insulating film formed over the cap insulating film, the inter layer insulating film including a silicon oxide film.

### BRIEF DESCRIPTION OF THE DRAWINGS

Other objects, features and advantages of the present disclosure will become clear upon reviewing the following description of the embodiment of the present disclosure with reference to the accompanying drawings, in which,

FIG. 1 illustrates an electrical configuration of a memory cell region described in a first embodiment of the present disclosure;

FIG. 2 illustrates a schematic plan view of the memory cell region;

FIG. 3 is a schematic cross sectional view taken along line 3-3 of FIG. 2;

FIGS. 4 to 13 are schematic vertical cross sectional views illustrating one phase of manufacturing steps;

FIG. 14 corresponds to FIG. 8 and illustrates a second embodiment of the present disclosure;

FIG. 15 corresponds to FIG. 9; and

FIG. 16 corresponds to FIG. 3 and illustrates a third embodiment of the present disclosure.

### DETAILED DESCRIPTION

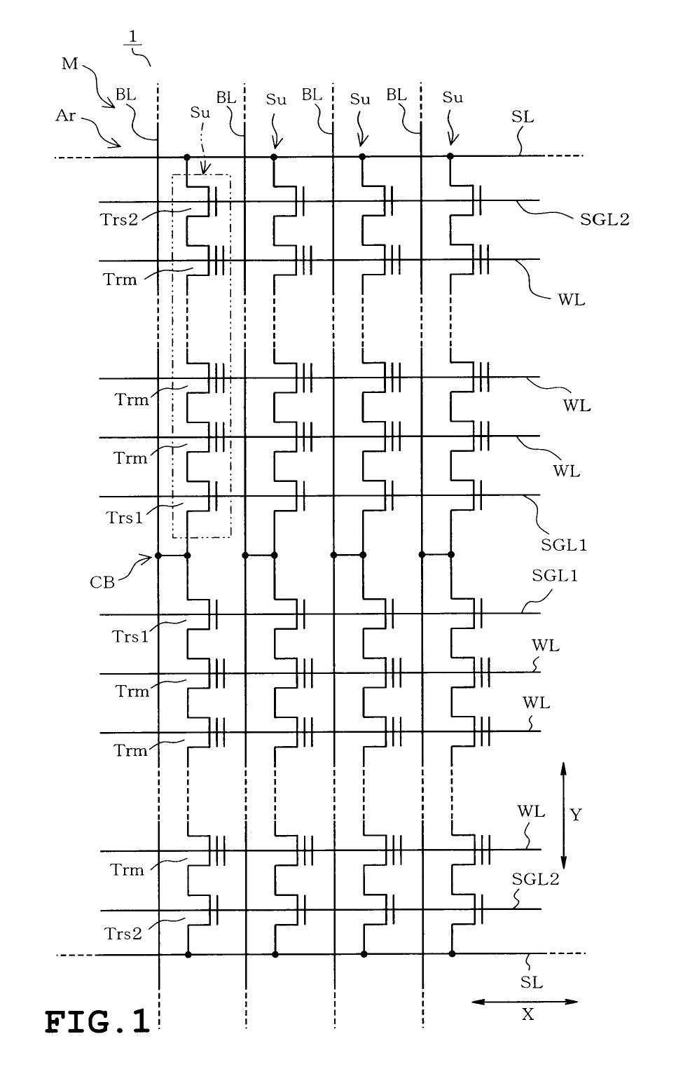

One embodiment employing the present disclosure to a NAND flash memory will be described with reference to FIGS. 1 to 13. References are made to the drawings herein after with identical or similar reference symbols when referring to identical or similar elements. Of note is that the drawings are merely schematic and the relation between the thickness and the planar dimensions and the ratio in thickness of each layer differs from the actual ratio.

First, a description will be given on the electrical configuration of the NAND flash memory of the present embodiment. FIG. 1 illustrates an equivalent circuit representing a portion of a memory cell array formed in the memory cell region of the NAND flash memory.

The memory cell array Ar of a NAND flash memory 1 is configured by a matrix of NAND cell units (string unit) Su. The NAND cell unit Su is constituted by two (a plurality of) select gate transistors Trs1, Trs2, and a plurality of memory cell transistors Trm connected in series between the two select gate transistors Trs1 and Trs2.

The plurality of neighboring memory cell transistors Trm shares source/drain regions within a single NAND cell unit Su. Referring to FIG. 1, the memory cell transistors Trm aligned in an X-direction (corresponding to word line direction) are connected to a common word line (control gate line) WL. Also, the select gate transistors Trs1 aligned in the X-direction in FIG. 1 are connected to a common select gate line SGL1. The select gate transistors Trs2 are connected to a common select gate line SGL2.

A bit line contact CB is connected to a drain region of the select gate transistor Trs1. The bit line contact CB is connected to a bit line BL extending in the Y-direction (corresponding to the bit line direction) perpendicularly crossing the X-direction indicated in FIG. 1. The select gate transistors Trs2 are connected to a source line SL via the source region.

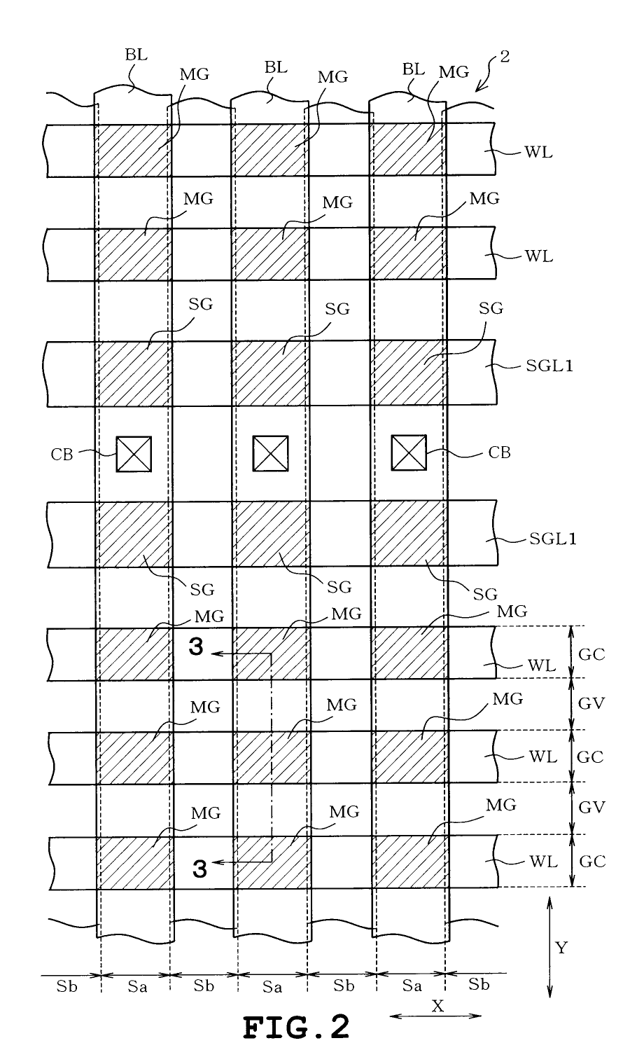

FIG. 2 is a plan view indicating a layout of a portion of the memory cell region. A plurality of STI (shallow trench isolation) serving as an element isolation region Sb is formed to extend in the Y-direction as viewed in FIG. 2 spaced at predetermined intervals in the X-direction to form active regions Sa along the Y-direction as viewed in FIG. 2 isolated in the X-direction.

A plurality of word lines WL of memory cell transistors are formed along the direction (X-direction) crossing over the active region Sa, each word line WL being spaced apart from one another in the Y-direction. Also, a pair of select gate lines SGL 1 for a pair of select gate transistors is formed along the X-direction as viewed in FIG. 2. Bit line contacts CB are formed on the active region Sa between the pair of select gate lines SGL1. A gate electrode MG (laminated gate electrode) of the memory cell transistor is formed at the crossover of the active region Sa and the word line WL, and a gate electrode SG of a select gate transistor is formed at the crossover of the active region Sa and the select gate line SGL1.

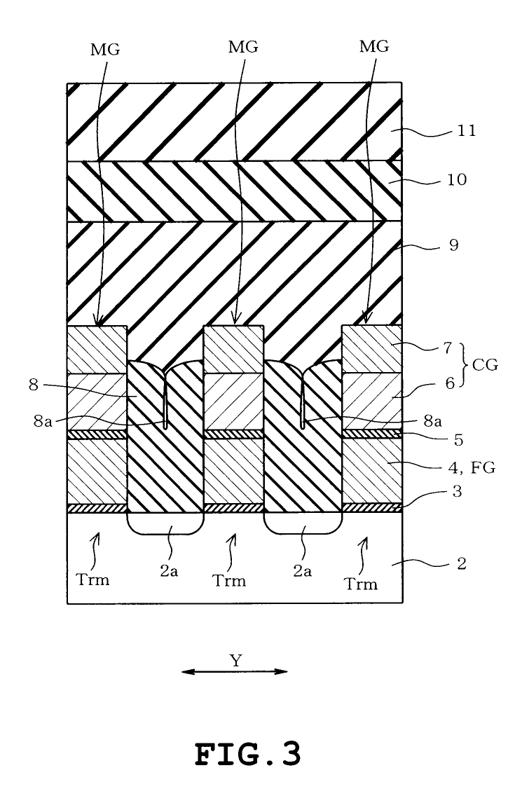

FIG. 3 is a schematic cross sectional view taken along line 3-3 of FIG. 2. FIG. 3 illustrates the structure of the gate electrode MG provided over the active region Sa and its peripheral structures that constitute the features of the present embodiment. As can be seen in FIG. 3, the gate electrode MG of the memory cell transistor is configured by laminating a polycrystalline layer 4, an ONO layer 5, a polycrystalline silicon layer 6, and a cobalt silicide (CoSi₂) layer 7 in the listed sequence over the silicon silicon oxide film 3 formed on the silicon substrate 2.

The silicon oxide film 3 is formed by thermally oxidizing the surface of the silicon substrate 2 and serves as a gate insulating film and a tunnel insulating film. The polycrystalline silicon layer 4 is doped with impurities such as phosphorous and constitutes the floating gate electrode FG. The polycrystalline silicon layer 6 is doped with impurities such as phosphorous and constitutes the base layer of the control gate electrode CG. The cobalt silicide layer 7 is an alloy layer for reducing the resistance of the word line formed on the base layer of the control gate electrode CG.

The control gate electrode CG is composed of the polycrystalline silicon layer 6 and the cobalt silicide layer 7. The ONO film 5 is a film composed of laminated layers of silicon oxide film-silicon nitride film-silicon oxide film, and serves as an inter-gate insulating film between the floating gate electrode FG and the control gate electrode CG, an interpoly insulating film or inter-conductive layer insulating film of the polycrystalline layers 4 and 6.

A lightly doped impurity diffusion layer 2a serving as a source/drain region is formed in the surface layer of the silicon substrate 2 situated between the gate electrodes MG of the memory cell transistors. A silicon oxide film 8 serving as an inter-electrode insulating film is formed on the silicon substrate 2 between the gate electrodes MG.

An inter layer insulating film 9 is formed on the silicon oxide film 8. The inter layer insulating film 9 is a silicon oxide film formed by high-density plasma CVD (HDP-CVD) by using TEOS (Tetra Ethoxy Silane) gas and is formed between and above the neighboring gate electrodes MG.

A silicon nitride film 10 serving as a barrier film is formed on the inter layer insulating film 9, and an inter layer insulating film 11 is formed on the silicon nitride film 10. The inter layer insulating film 11 is made from silicon oxide film by HDP-CVD.

Next, a description will be given on the manufacturing method of the above described structure, focusing on the features of the present embodiment. Any of the following steps may be eliminated as required and likewise, any steps required for forming the structures of the flash memory 1 not shown may be added as required.

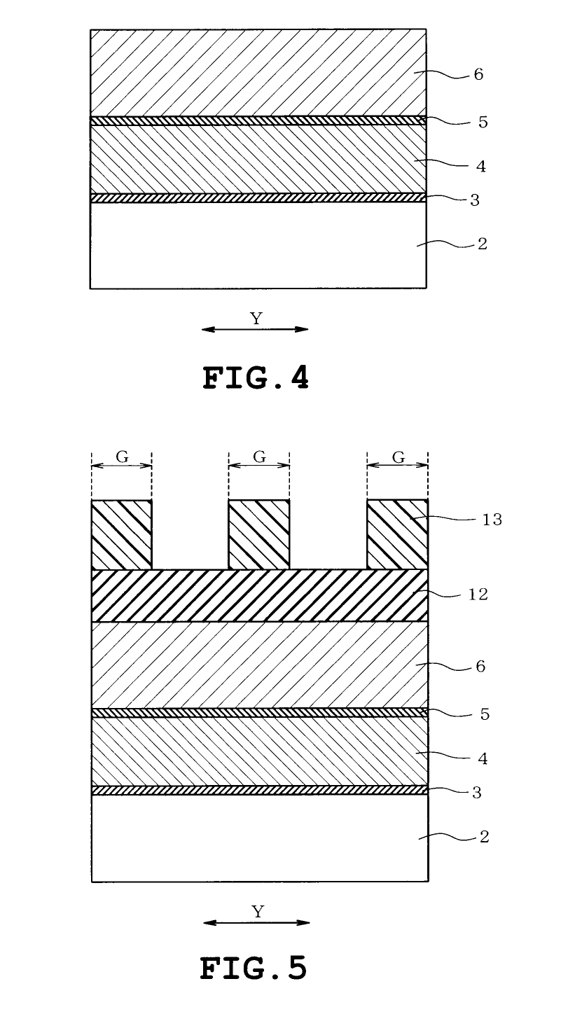

Referring to FIG. 4, a well (not shown) is formed in the silicon substrate 2, whereafter a silicon oxide film 3 is formed by thermal oxidation. Then, the polycrystalline silicon layer 4, the ONO film 5, and the polycrystalline silicon layer 6 constituting the base layer of the control gate electrode CG are laminated sequentially by LP-CVD (Low Pressure CVD).

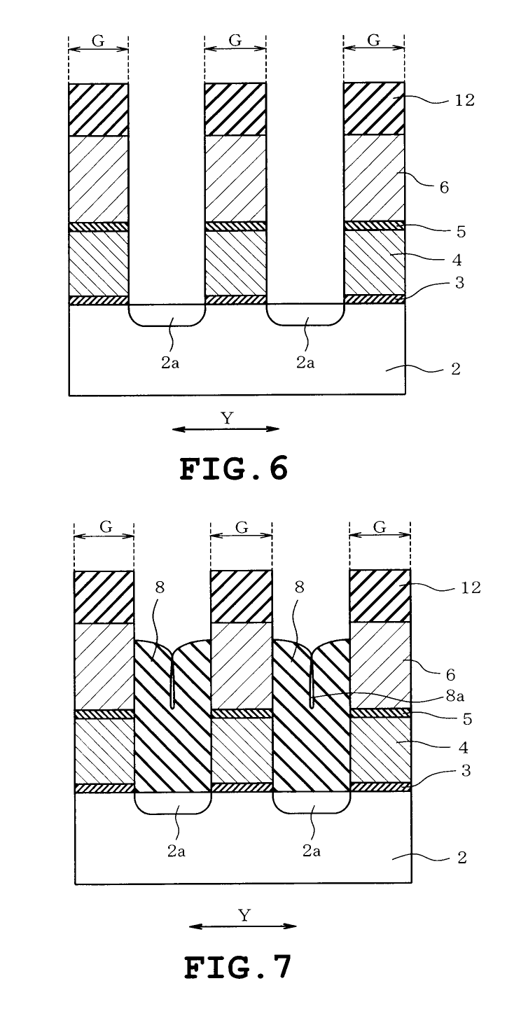

Next, referring to FIG. 5, a silicon nitride film 12 constituting a mask pattern is formed on the upper surface of the polycrystalline silicon layer 6. Then, the silicon nitride film 12 upper surface is coated by a resist 13 and thereafter patterned by photolithography process. Then, referring to FIG. 6, the silicon nitride film 12 is separated by dry etch such as RIE (Reactive Ion Etching). Thereafter, as illustrated in FIG. 6, the separated nitride film 12 is used as a mask for separating the laminated films 3 to 6 in the gate electrode forming region G by RIE. The gate electrode forming region G is a region in which the gate electrode MG of the memory cell transistors are formed. Then, the resist 13 is removed and the surface layer of the silicon substrate 2 is lightly doped with n-type impurities by ion implantation to form a source/drain region.

The resist 13 may be removed immediately after separating the silicon nitride film 12. In the present embodiment, the silicon oxide film 3 situated between the gate electrode forming regions G for forming the gate electrodes MG has been separated as well; however, it may be maintained without being removed.

Referring to FIG. 7, the silicon oxide film 8 is formed on the impurity diffusion layer (source/drain region) 2a by LP-CVD using TEOS gas in the temperature range of 600 to 800 degrees Celsius. Given the narrow lateral (Y-directional) spacing and the high aspect ratio of the separated region, seams 8a are created in the upper mid portion of the silicon oxide film 8. Next, the silicon oxide film 8 is etched back by RIE so as to be lower than the upper surface of the polycrystalline silicon layer 6 but higher than the lower surface of the polycrystalline silicon layer 6. The silicon oxide film 8, however, maybe further etched back to the height equal to or higher than the underside of the ONO film 5.

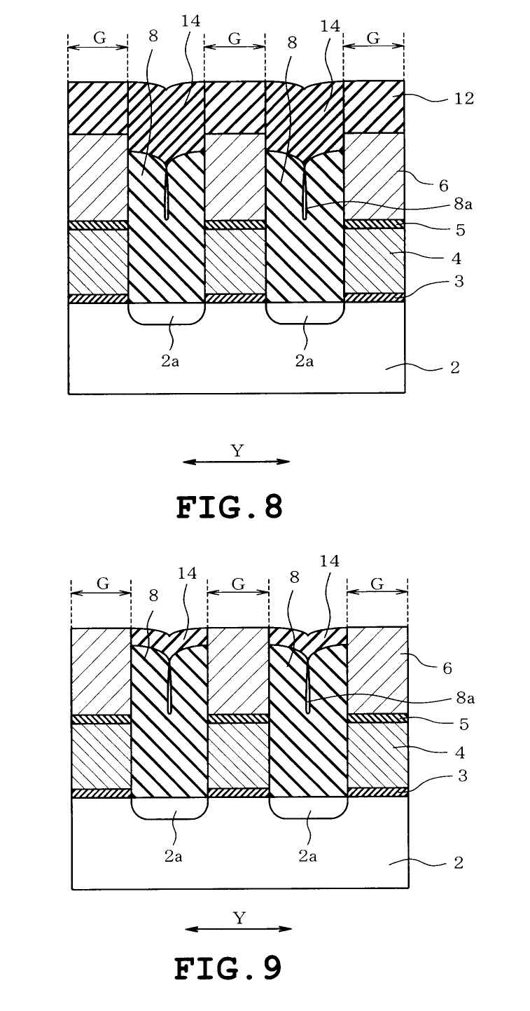

Next, referring to FIG. 8, the silicon nitride film 14 is deposited on the silicon oxide film 8 by LP-CVD in the temperature range of 650 to 800 degrees Celsius. The silicon nitride film 14 is etched back as required to be of substantially the same height as the upper surface of the silicon nitride film 12. The silicon nitride film 14 serves as a cap insulating film having higher-selectivity to the silicon oxide film 8 during the etch process.

Next, referring to FIG. 9, the silicon nitride films 12 and 14 are etched by RIE until the upper surface of the polycrystalline silicon layer 6 is exposed, at which point the etch is stopped. Next, the exposed surface of the polycrystalline silicon layer 6 is cleaned and exposed again by removing the native oxide film, and the like by treatments such as dilute HF treatment. The silicon nitride films 12 and 14 have selectivity ratios of or greater than hundred to one relative to silicon oxide film 8 in the wet etch process by dilute HF. Thus, seams 8a, if any, in the upper mid portion of the silicon oxide film 8 will not increase in size since the silicon oxide film 8 is not removed during wet etch by the protection of the silicon nitride film 14 serving as the cap film.

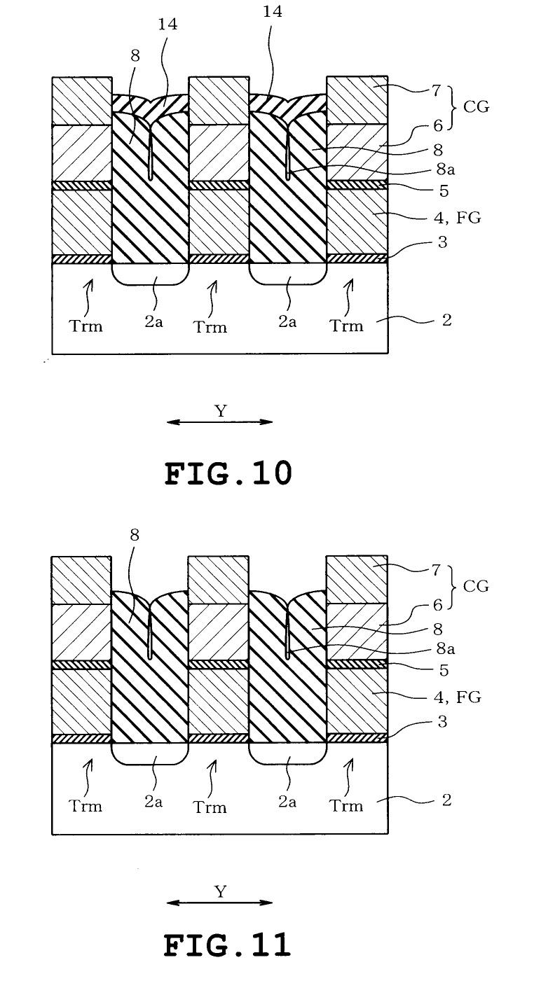

Next, referring to FIG. 10, cobalt silicide (CoSi₂) film 7 is formed on the upper portion of the polycrystalline silicon layer 6 by succession of steps including consecutive sputtering of cobalt (Co)/titanium (Ti)/nitride titanium (TiN), thermal treatment such as lamp anneal and removing of non-reactive metal. Cobalt may be replaced by other metal such as tungsten.

Next, referring to FIG. 11, the silicon nitride film 14 is removed by dry etch with high selectivity to polycrystalline silicon layer 6. The silicon nitride film 14 is removed because the presence of the silicon nitride film 14 between the neighboring polycrystalline silicon layers 6 causes increase in parasitic capacitance. Thus, removing the silicon nitride film 14 suppresses the parasitic capacitance between the neighboring gate electrodes MG.

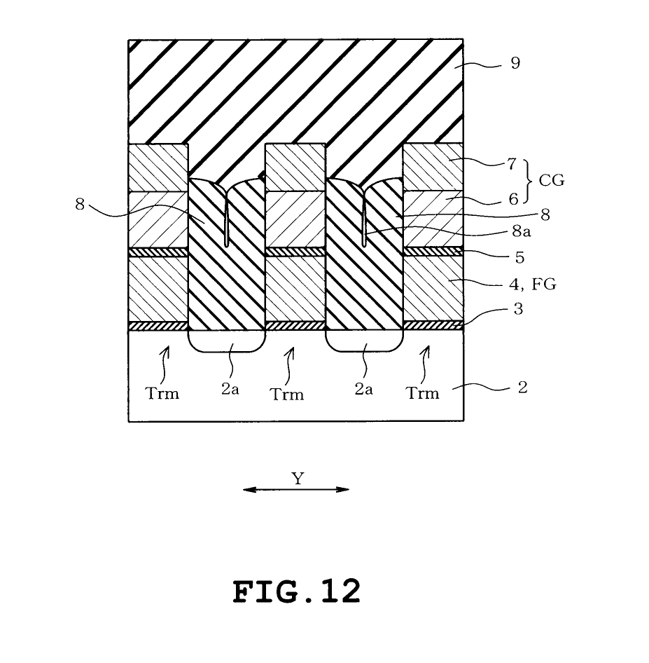

Next, referring to FIG. 12, the silicon oxide film 9 is filled between the neighboring cobalt silicide films 7 by forming the silicon oxide film 9 serving as an inter layer insulating film on the cobalt silicide film 7 and the silicon oxide film 8 by HDP-CVD.

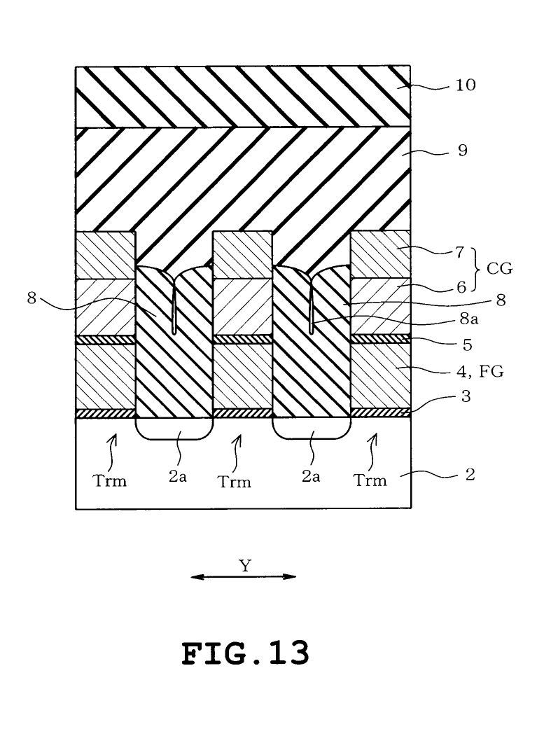

Next, referring to FIG. 13, the silicon nitride film 10 is formed on the silicon oxide film 9. The silicon nitride film 10 serves as a barrier film for preventing intrusion of hydrogen and impurity ions contained in the overlying inter layer insulating film 11 into the gate insulating films such as the silicon oxide film 3 and the ONO film 5.

Then, as illustrated in FIG. 3, the inter layer insulating film 11 is deposited on the silicon nitride film 10 by HDP-CVD. Thereafter, thought not described in detail, bit line contacts CB and upper layer interconnects are formed further on top.

Of note is that the upper surface of the polycrystalline silicon layer 6 must be cleaned and exposed immediately before forming the cobalt silicide film 7 on the polycrystalline silicon layer 6 in order to effectively reduce the resistance of the control gate electrode CG.

According to the present embodiment, the silicon nitride film 14 is formed on the silicon oxide film 8 and on the side surfaces of the polycrystalline silicon layer 6. Then, the silicon nitride film 12 on the polycrystalline silicon layer 6 is removed by RIE and further wet etched to remove the native oxide films, and the like. Thus, seams 8a, if any, formed in the upper mid portion of the silicon oxide film 8 will not increase in size in the wet etch for cleaning the upper surface of the polycrystalline silicon layer 6 since the seams 8a are covered by the silicon nitride film 14 serving as the cap insulating film. Such being the case, seams 8a, if any, formed in the upper mid portion of the silicon oxide film 8 will not increase in size nor allow intrusion of unwanted elements, thereby preventing device errors.

Since the silicon nitride film 14 covering the upper surface of the silicon oxide film 8 is formed by the same material as the silicon nitride film 12 used as a hard mask, the silicon nitride films 12 and 14 can be thinned simultaneously, thereby reducing the manufacturing steps.

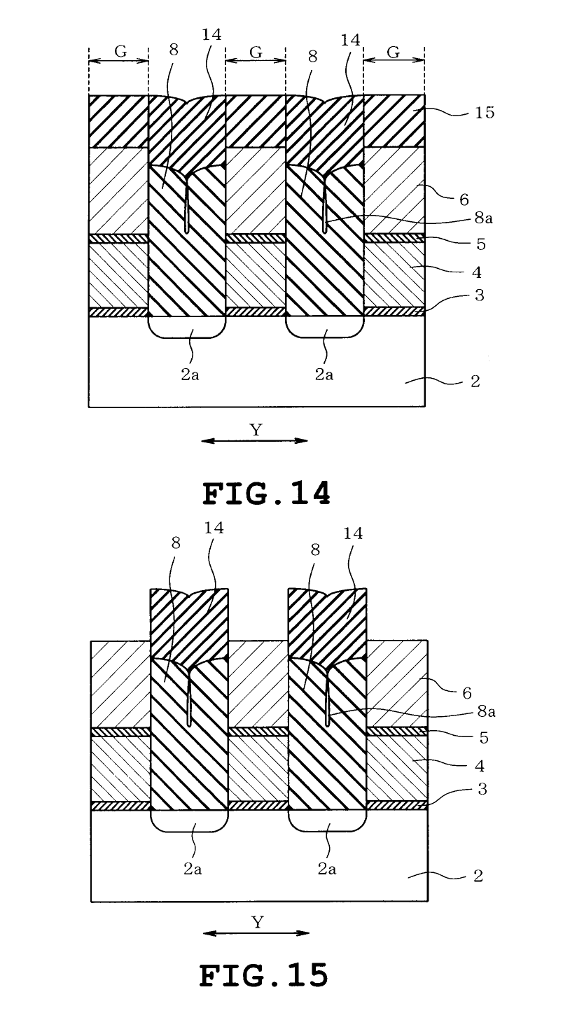

FIGS. 14 to 15 illustrate a second embodiment of the present disclosure. The second embodiment differs from the first embodiment in that an oxide-based material is used instead of the silicon nitride film 12 serving as the mask. Portions that are identical to the first embodiment are identified with identical reference symbols and a description will only be given on the portions that differ.

FIG. 14 schematically illustrates the state where the silicon nitride film 14 is etched back to the height of the upper surface of the silicon oxide film 15 by using the silicon oxide film 15 as a mask instead of the silicon nitride film 12. In other words, FIG. 14 corresponds to FIG. 8 described in the aforementioned embodiment.

After completing the step illustrated in FIG. 14, the silicon oxide film 15 is etched by RIE to expose the upper surface of the polycrystalline silicon layer 6. The silicon oxide film is etched with higher selectivity to silicon nitride film 14. This allows the silicon oxide film 15 to be removed without removing the silicon nitride film 14. In other words, the etch process can be carried out without exposing the side surfaces of the polycrystalline silicon layer 6. Next, cobalt silicide film 7 is formed by series of steps carried out in the first embodiment. The subsequent steps will not be described since they are the same as the first embodiment and provide substantially the same results.

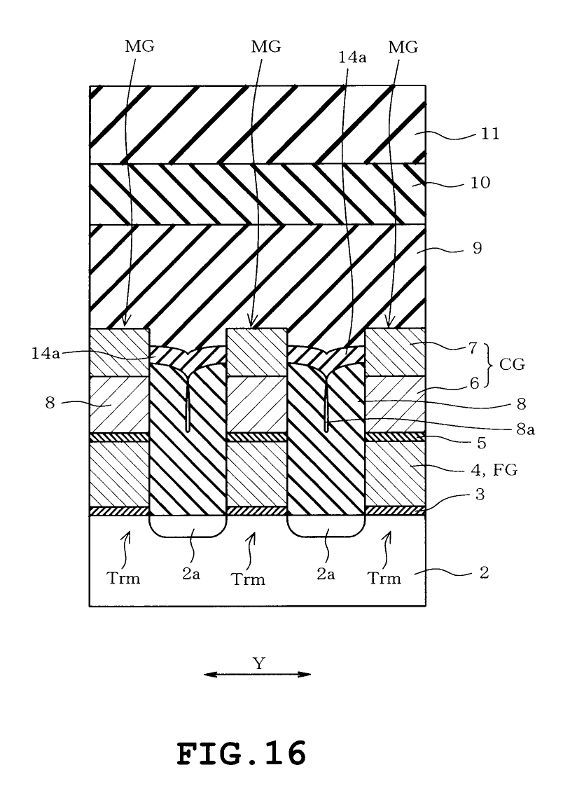

FIG. 16 illustrates the third embodiment of the present disclosure. The third embodiment differs from the first embodiment in that silicon nitride film 14a is maintained. Portions that are identical to the first embodiment are identified with identical reference symbols and a description will only be given on the portions that differ.

In the first embodiment, dry etch is carried out after formation of the structure illustrated in FIG. 10 to remove the silicon nitride film 14 as illustrated in FIG. 11, whereafter the silicon oxide film 9, the silicon nitride film 10, and the inter layer insulating film 11 are laminated sequentially. In this case, boron is introduced into the silicon nitride film 14a to reduce the relative dielectric constant (∈ᵣ) to approximately 4 to 5 from 7.9 of an ordinary silicon nitride film. The third embodiment also provides substantially the same results as the above described embodiments.

The present disclosure is not limited to the above embodiments but may be modified or expanded as follows.

The present disclosure has been applied to the flash memory 1; however, it may be applied to other semiconductor devices manufactured by steps including forming an inter-electrode insulating film like silicon oxide film 8, and etching back the inter-electrode insulating film to a portion where seams 8a are formed.

The present disclosure employs the ONO film 5 as the gate insulating film between the floating gate electrode FG and the control gate electrode CG; however other materials having high dielectric constant such as alumina (Al₂O₃) may be employed instead.

In one embodiment of the present disclosure, the silicon oxide film 8 is formed directly on the silicon substrate 2 situated between the gate electrodes MG. However, the silicon oxide film 8 may be formed on the silicon substrate 2 via the silicon oxide film 3. The gate insulating film 3 immediately underlying the neighboring gate electrodes may be structurally connected.

The gate electrode MG may be replaced by a single layer gate electrode. Also, the present disclosure may be applied to a charge-trap type structure (the so called SONOS, MONOS structure) that employs a silicon nitride film as a floating gate electrode FG which is constituted by the polycrystalline silicon layer 4 in the embodiments of the present disclosure.

The foregoing description and drawings are merely illustrative of the principles of the present disclosure and are not to be construed in a limited sense. Various changes and modifications will become apparent to those of ordinary skill in the art. All such changes and modifications are seen to fall within the scope of the disclosure as defined by the appended claims.

What is claimed is:

1. A method of manufacturing a semiconductor device, comprising:
forming a gate insulating film on a semiconductor substrate;
forming a gate electrode film on the gate insulating film;
forming a mask film on the gate electrode film;
separating the gate electrode film by using the mask film as a mask pattern to form a plurality of gate electrodes;
forming a first insulating film between the plurality of gate electrodes so that an upper portion of the first insulating film is lower than an upper surface of the gate electrode;
forming a second insulating film on the upper portion of the first insulating film so as to cover the first insulating film;
removing the mask film leaving the second insulating film on the first insulating film so as to expose the gate electrode; and
cleaning an exposed surface of the gate electrode by wet etching process with selectivity to the second insulating film so as to remove a native oxide film.

2. The method of claim 1, wherein the gate electrode film includes a polycrystalline silicon film, the first insulating film includes a silicon oxide film, and the mask film and the second insulating film include a silicon nitride film.

3. The method of claim 2, further comprising removing the second insulating film after the cleaning.

4. The method of claim 2, further comprising forming an alloy layer at an upper portion of the gate electrode film.

5. The method of claim 4, further comprising forming an inter layer insulating film including a silicon oxide film on the first insulating film and the alloy layer.

6. The method of claim 1, wherein the wet etching process includes a dilute HF treatment.

7. The method of claim 4, wherein the alloy layer includes a silicide layer.

8. The method of claim 7, wherein the silicide layer includes a cobalt silicide layer.

9. The method of claim 1, wherein the mask film includes a silicon oxide film.

10. The method of claim 1, further comprising forming an inter layer insulating film on the second insulating film.

11. The method of claim 10, wherein the second insulating film includes a boron (B).

12. The method of claim 2, wherein the gate electrode film includes a floating gate electrode portion formed on the gate insulating film, a control gate electrode portion formed above the floating gate electrode portion and an inter gate insulating film formed between the floating and the control gate electrode portions.

13. The method of claim 12, wherein the inter gate insulating film includes a pair of silicon oxide films and a silicon nitride film formed between the silicon oxide films.

14. The semiconductor device, comprising:
a semiconductor substrate including an upper surface;
a gate insulating film formed on the upper surface of the semiconductor substrate;
a plurality of gate electrodes formed on the gate insulating film;
an inter-electrode insulating film formed on the gate insulating film between the plurality of gate electrodes, the inter-electrode insulating film including a seam and including a silicon oxide film;
a cap insulating film formed so as to cover the inter-electrode insulating film, the cap insulating film including a silicon nitride film containing a boron (B); and
an inter layer insulating film formed over the cap insulating film, the inter layer insulating film including a silicon oxide film.

15. The device of claim 14, wherein the gate electrode includes a floating gate electrode on the gate insulating film, an inter-gate insulating film, and a control gate electrode.
